(19) United States
(12) Patent Application Publication
(10) Pub. No.: US 2015/0307753 A1
(43) Pub. Date: Oct. 29, 2015

(54) Conductive Resilient Hollow Microsphere, Adhesive Composition, and Adhesive Articles

(71) Applicants: Weide LIU, (US); Badri VEERARAGHAVAN, (US); Cecil V. FRANCIS, (US); Yiwen CHU, (US); Jing FANG, (US)

(72) Inventors: WeiDe Liu, Shanghai (CN); Badri Veeraraghavan, Woodbury, MN (US); Cecil V. Francis, Austin, TX (US); Yiwen Chu, Shanghai (CN); Jing Fang, Shanghai (CN)

(73) Assignee: 3M Innovation Properties Company

(21) Appl. No.: 14/441,486

(22) PCT Filed: Nov. 16, 2012
(86) PCT No.: PCT/CN2012/084785

§ 371 Date: May 7, 2015

(51) Int. Cl. C09J 9/02; C23C 14/35; C23C 14/20; B32B 7/12

(52) U.S. Cl. CPC C09J 9/02; B32B 7/12; C23C 14/35; C23C 14/205; B32B 2255/26; B32B 2264/02; B32B 2457/00

(57) ABSTRACT

A conductive resilient hollow microsphere comprises a conductive layer enclosing a resilient polymeric hollow microsphere. An adhesive composition includes an insulating adhesive component and a plurality of the conductive resilient hollow microspheres. Adhesive articles including the adhesive composition are also disclosed. Methods of making the same are also disclosed.

### BACKGROUND

Conductive adhesives are used in the electronics industry to form conductive bonds between conductive leads of electrical components. Conductive adhesive typically have an adhesive matrix containing conductive particles such as metal-coated glass microbubbles and/or conductive fibers.

Conductive adhesives may be conductive throughout or only in certain dimensions. For example, the conductive adhesive may be anisotropic in its conductivity, with conductivity manifested only in the direction of the adhesive bond thickness (z-axis).

EMI shielding gaskets (EMI gaskets) are used on various types of electronic equipment to provide protection against interference from electromagnetic energy, including radio frequency interference (RFI) and more broadly all bands of interference commonly called electromagnetic interference (EMI). EMI shielding gaskets generally include an electrically conductive element, be it a wire mesh, conductive filler or conductive plating, coating or fabric which prevents external EMI from interfering with an electronic device and/or protects other adjacent electronic devices from EMI emitted by an electronic device.

### SUMMARY

For most applications conductivity and/or durability of the adhesive bond are important properties of conductive adhesives. Accordingly, there is a continuing need for conductive adhesives and particles having improved performance properties.

In one aspect, the present disclosure provides a conductive resilient hollow microsphere comprising a conductive layer enclosing a resilient polymeric hollow microsphere. In some embodiments, the resilient polymeric hollow microsphere comprises a copolymer of acrylonitrile and methacrylonitrile. In some embodiments, the conductive layer comprises silver or stainless steel.

In another aspect, conductive resilient hollow microspheres according to the present disclosure can be made by a method comprising contacting resilient polymeric hollow microsphere with a vapor of a metal at a pressure in the range of from 10 millitorr (13.3 Pa) to 100 millitorr (133 Pa), inclusive, for at least sufficient time to deposit a substantially uniform and complete layer of the metal onto the surface of the resilient organic microspheres.

Conductive resilient hollow microspheres according to the present disclosure are suitable for use in, for example, conductive adhesives and EMI shielding gaskets.

Accordingly, in another aspect, the present disclosure provides an adhesive composition comprising:

an insulating adhesive component; and

conductive resilient hollow microspheres according to the present disclosure. In some embodiments, the insulating adhesive component comprises at least one of an acrylic adhesive or a silicone adhesive. In some embodiments, the conductive adhesive is a pressure-sensitive adhesive. In some embodiments, the pressure-sensitive adhesive further comprises conductive filler particles.

Advantageously, conductive resilient hollow microspheres according to the present disclosure are suitable for inclusion in adhesives wherein compressibility of the adhesive layer is important (e.g., as in the case of foam tapes and/or gaskets). In such applications, the conductive resilient hollow microspheres may provide a durable adhesive bond that is z-axis conductive and provides EMI shielding in the x and y axes directions.

Accordingly, in another aspect, the present disclosure provides an adhesive article comprising a layer of the adhesive composition according to the present disclosure, wherein the layer of the adhesive composition is releasably adhered to a first major surface of a first substrate. In some embodiments, the adhesive article further comprises a second substrate, wherein the layer of the adhesive composition is releasably adhered to a major surface of the second substrate, and wherein the layer of the adhesive composition is disposed between the first substrate and the second substrate. In some embodiments, the substrate has a second major surface opposite the first major surface, and wherein the layer of the adhesive composition is releasably adhered to the second major surface of the first substrate.

As used herein:

the term “conductive” means electrically conductive at least at the surface (e.g., having a surface conductivity greater than or equal to that of stainless steel, nickel, or silver);

the term “hollow microsphere” refers to a hollow substantially spherical particle in the size range of from 0.1 microns to 1000 microns;

the term “releasably adhered” means removable by hand without aid of tools (e.g., a crowbar, pliers, chisel) and without causing substantial physical damage to a substrate to which it is adhered; and

the term “resilient” means capable of regaining its original shape or position after substantial bending, stretching, compression, or other deformation.

The features and advantages of the present disclosure will be further understood upon consideration of the detailed description as well as the appended claims.

### BRIEF DESCRIPTION OF THE DRAWINGS

FIG. 1 is a cross-sectional schematic side view of an exemplary conductive resilient hollow microsphere according to the present disclosure;

FIG. 2 is a cross-sectional schematic side view of an exemplary adhesive article according to the present disclosure; and

FIG. 3 is cross-sectional schematic side view of another exemplary adhesive article according to the present disclosure.

Repeated use of reference characters in the specification and drawings is intended to represent the same or analogous features or elements of the disclosure. It should be understood that numerous other modifications and embodiments can be devised by those skilled in the art, which fall within the scope and spirit of the principles of the disclosure. The figure may not be drawn to scale.

### DETAILED DESCRIPTION

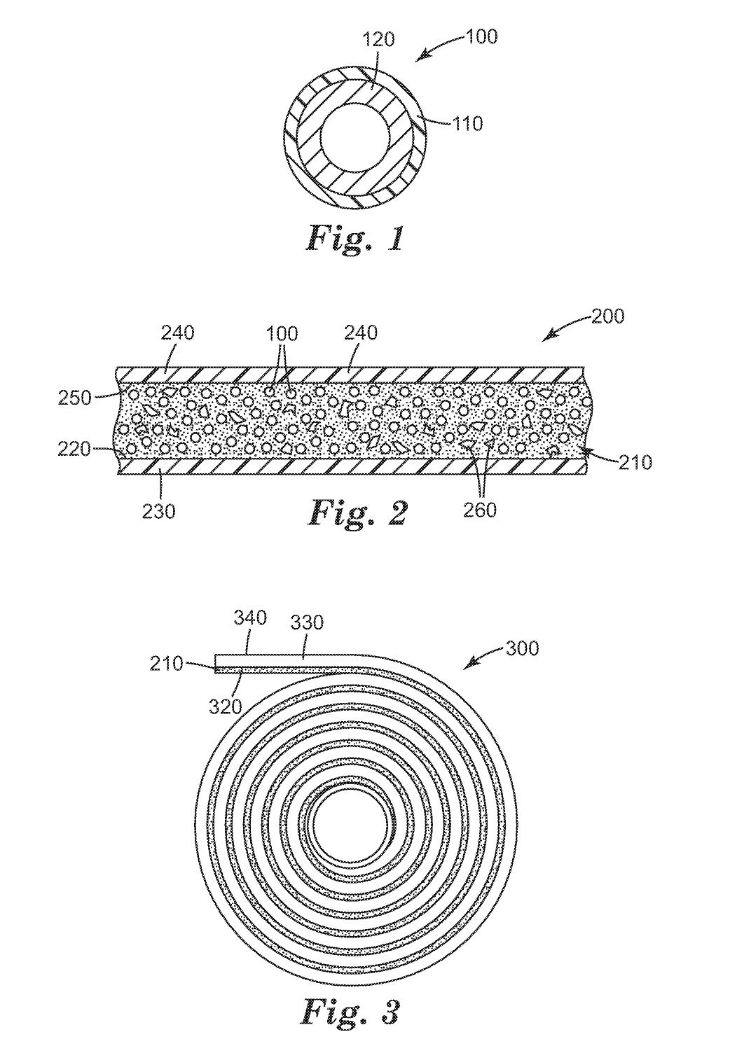

Referring now to FIG. 1, exemplary conductive particle 100 comprises a conductive layer 110 enclosing resilient polymeric hollow microsphere 120.

Useful resilient polymeric hollow microsphere may comprise, consist essentially of (i.e., contain one or more additional components that do not substantially affect the resiliency of the resilient polymeric hollow microsphere), or even consist of one or more organic polymers such as, for example, a resilient polymer (i.e., an elastomer) and/or rubber in sufficient quantity to impart softness and resilience.

Examples of suitable elastomers include elastomeric polyurethanes, acrylic elastomers (e.g., acrylonitrile-methacrylonitrile elastomers), ethylene copolymers such as ethylene vinyl acetates, ethylene/propylene copolymer elastomers, silicone elastomers, fluorosilicone elastomers, non-silicone fluoroelastomers, segmented thermoplastic elastomers (segmented polyester thermoplastic elastomers, segmented polyurethane thermoplastic elastomers, segmented polyurethane thermoplastic elastomers blended with other thermoplastic materials, segmented polyamide thermoplastic elastomers, and ionomeric thermoplastic elastomers). As used herein, the term “segmented thermoplastic elastomer” refers to the sub-class of thermoplastic elastomers which are based on polymers which are the reaction product of a high equivalent weight polyfunctional monomer and a low equivalent weight polyfunctional monomer. Blends of the foregoing elastomers with each other or with modifying non-elastomers may also be used.

Examples of suitable rubbers include natural and synthetic rubbers (e.g., ethylene propylene diene monomer (EPDM) rubbers, nitrile rubbers, chloroprene rubbers, fluorocarbon rubbers, ethylene propylene (EPM) rubbers, and silicone rubbers).

Resilient polymeric hollow microspheres are available commercially. For example, resilient hollow microspheres comprising an acrylonitrile-methacrylonitrile copolymer are available under the trade designations MP11 (bulk density of about 0.1 grams per cubic centimeter (g/mL), anti-pressure>20 millipascals (mPa), average particle diameter 15-30 microns) and MP14 (bulk density of about 0.01 g/mL, anti-pressure>20 mPa, average particle diameter 20-100 microns) from Guangzhou Eco. and Chemie Trading Co. Ltd. of Guangzhou, Guangdong, China. Additional resilient polymeric hollow microspheres are available from Sphere One Inc. of Chattanooga, Tenn. as PM 6550 HOLLOW SPHERES (flexible plastic hollow spheres bulk density 0.05 g/mL, mean particle size 100 microns, mean particle size range 10-200 microns, density 0.030 g/mL).

Typical conductive resilient hollow microsphere diameters are in a range from 0.1 to 500 microns, and preferably in a range from 1 to 200 microns, although other diameters can be used.

The conductive layer may be any conductive material. For example, the conductive layer may comprise a conducting polymer, inorganic oxide, or metal. Typically, the conductive layer comprises at least one metal. Examples of suitable metals include, nickel, gold, silver, stainless steel, aluminum, platinum, palladium, chromium, copper. Alloys and combinations of metals (including, e.g., the foregoing metals) may also be used. The conductive layer may have any thickness, but typically has a thickness in a range of from one nanometer (nm) to one micron, desirably in a range of from 10 nm to 200 nm, and more desirably in a range of from 20 to 60 nm. The conductive layer may be disposed on resilient polymeric hollow microspheres by any suitable method including, for example, chemical methods (e.g., chemical vapor deposition), and physical methods such as thermal vapor deposition or sputter deposition. Of these, physical vapor deposition (PVD) is preferred.

PVD of metals is a well-established practice in the coating art. Physical vapor deposition of the conductive layer can be carried out in various different ways. Representative approaches include sputter deposition, evaporation, laser ablation, and cathodic arc deposition. Any of these or other PVD approaches can be using in the process of the invention, although the nature of the PVD technique can impact the resulting activity. Energy of the PVD technique can impact the mobility of the deposited metal and hence its tendency to coalesce and form a continuous thin film encapsulating each resilient polymeric hollow microspheres.

Generally, the energy of the depositing species depends on the process (lower for evaporation and higher for sputtering) and background process pressures during the deposition. In general, deposition of metals under low-pressure conditions results in dense continuous thin films. In addition, the temperature of the substrate onto which the metal is deposited will increase significantly high due to high energy impact and condensation of metal vapor. This dense film can also induce compressive stress in the plastic hollow microspheres. These effects can reduce the resiliency of the metal coated resilient polymeric hollow microspheres, and may even collapse them under some circumstances. Moreover, dense metal films do not have compressible properties as that of the substrate plastic bubbles, and they may break upon compression.

Sputter deposition is typically carried out at a deposition pressure of less than about 10 millitorr (1.33 Pa). However, in order to achieve a metal coating on the resilient polymeric hollow microspheres with resilience as well as conductivity, the present inventors have found that by deposit metal under conditions such that the metal vapor condenses onto the substrate with low energy, which can be achieved using relatively high-pressure conditions during the sputter deposition process.

The present inventors have unexpectedly discovered that by using vapor deposition pressures of ≧ about 2 Pa, under conditions such that the metal vapor condenses onto the substrate with low energy, it is possible to coat metal (e.g., silver), onto resilient polymeric hollow microspheres without collapsing the microspheres. Additionally, the metal-coated resilient polymeric hollow microspheres show compressibility similar to that of the uncoated resilient polymeric hollow microspheres, without substantial amounts of breakage, and while maintaining a high level of electrical conductivity. Due to decreased productivity and/or yield it is desirable to have a maximum deposition pressure of less than or equal to about 100 millitorr (13.3 Pa). Preferably, the metal deposition pressure during physical vapor deposition is the range of from 2 Pa to 13 Pa, more preferably from 2 Pa to 8 Pa, and more preferably from 2 Pa to 5 Pa.

Conductive resilient hollow microspheres according to the present disclosure are useful; for example, in formulation of adhesive compositions (e.g., conductive adhesive compositions and/or EMI shielding adhesive compositions). The adhesive compositions may be, for example, thermosetting, thermoplastic, pressure-sensitive, or a combination thereof. Exemplary adhesive compositions comprise an insulating adhesive component and conductive resilient hollow microspheres according to the present disclosure. Exemplary thermosetting insulating adhesive components include epoxy resins, free-radically polymerizable acrylic resins (e.g., acrylates and methacrylates), cyanates, polyurethane precursors, polymerizable silicones, and combinations thereof. Exemplary thermoplastic insulating adhesive components include polyamides, polyolefins, polyesters, thermoplastic polyurethanes (TPUs), polyethers, cellulosic esters, and combinations thereof. Exemplary pressure-sensitive insulating adhesive components include: tackified natural rubbers; synthetic rubbers; tackified linear, radial, star, and branched and tapered styrene block copolymers, such as styrene-butadiene, styrene-ethylene/butylene and styrene-isoprene; polyurethanes; polyvinyl ethers; acrylics, especially those having long chain alkyl groups; poly-alpha-olefins; and silicones. Useful acrylic pressure-sensitive components are described in, for example, U.S. Pat. No. 6,632,522 (Hyde et al.); U.S. Pat. No. 5,654,387 (Bennett et al.); U.S. Pat. No. 5,708,109 (Bennett et al.); U.S. Pat. No. 5,229,206 (Groves); Re 24,906 (Ulrich); U.S. Pat. No. 4,181,752 (Martens et al); U.S. Pat. No. 4,952,650 (Young et al.); and U.S. Pat. No. 4,569,960 (Blake).

Useful natural rubber pressure-sensitive adhesives generally contain masticated natural rubber, from 25 parts to 300 parts of one or more tackifying resins to 100 parts of natural rubber, and typically from 0.5 to 2.0 parts of one or more antioxidants per 100 parts of natural rubber. Natural rubber may range in grade from a light pale crepe grade to a darker ribbed smoked sheet and includes such examples as CV-60, a controlled viscosity rubber grade and SMR-5, a ribbed smoked sheet rubber grade.

Tackifying resins used with natural rubbers generally include but are not limited to wood rosin and its hydrogenated derivatives; terpene resins of various softening points, and petroleum-based resins, such as, the ESCOREZ 1300 series of C₅ aliphatic olefin-derived resins from ExxonMobil Chemical, Houston, Tex., and the “PICCOLYTE S” series of polyterpenes from Hercules, Inc. Wilmington, Del. Antioxidants are used to retard the oxidative attack on natural rubber, which can result in loss of the cohesive strength of the natural rubber adhesive. Useful antioxidants include but are not limited to amines, such as N,N′-di-β-naphthyl-1,4-phenylenediamine, available as AGERITE D from R.T. Vanderbilt, Norwalk, Conn.; phenolics such as 2,5-di-(t-amyl)hydroquinone, available as SANTOVAR A from Monsanto Chemical Co., St. Louis, Mo., tetrakis[methylene 3-(3′,5′-di-tert-butyl-4′-hydroxyphenyl)propionate]methane, available as IRGANOX 1010 from Ciba-Geigy Corp., Ardsley, N.Y.; 2,2′-methylene-bis-(4-methyl-6-tert-butylphenol); and dithiocarbamates such as zinc dithiodibutyl carbamate. Other materials can be added to natural rubber adhesives for special purposes, wherein the additions can include plasticizers, pigments, and curing agents to partially vulcanize the pressure-sensitive adhesive.

Another useful class of dielectric pressure-sensitive adhesives is that comprising synthetic rubber. Such adhesives are generally rubbery elastomers, which are either self-tacky or non-tacky and require tackifiers.

Self-tacky synthetic rubber pressure-sensitive adhesives include for example, butyl rubber, a copolymer of isobutylene with less than three percent isoprene, polyisobutylene, a homopolymer of isoprene, polybutadiene, or styrene/butadiene rubber. Butyl rubber pressure-sensitive adhesives often contain an antioxidant such as zinc dibutyl dithiocarbamate. Polyisobutylene pressure-sensitive adhesives do not usually contain antioxidants. Synthetic rubber pressure-sensitive adhesives, which generally require tackifiers, are also generally easier to melt process. They comprise polybutadiene or styrene/butadiene rubber, from 10 parts to 200 parts of a tackifier per 100 parts rubber, and generally from 0.5 to 2.0 parts per 100 parts rubber of an antioxidant such as IRGANOX 1010 from BASF, Ludwigshafen, Germany. An example of a synthetic rubber is AMERIPOL 1011A, a styrene/butadiene rubber from Ameripol Synpol, Akron, Ohio. Exemplary tackifiers that are useful include derivatives of rosins such as: FORAL 85, a stabilized rosin ester from Hercules, Inc.; the SNOWTACK series of gum rosins from Tenneco, Lake Forest, Ill.; the AQUATAC series of tall oil rosins from SylvaChem Corp., Memphis, Tenn.; synthetic hydrocarbon resins such as the PICCOLYTE A series, polyterpenes from Hercules, Inc.; the ESCOREZ 1300 series of C₅ aliphatic olefin-derived resins, the ESCOREZ 2000 Series of C₉ aromatic/aliphatic olefin-derived resins, and polyaromatic C₉ resins, such as the PICCO 5000 series of aromatic hydrocarbon resins, from Hercules, Inc. Other materials can be added for special purposes, including hydrogenated butyl rubber, pigments, plasticizers, liquid rubbers, such as VISTANEX LMMH polyisobutylene liquid rubber from ExxonMobil, and curing agents to vulcanize the adhesive partially.

Styrene block copolymer pressure-sensitive adhesives generally comprise elastomers of the A-B or A-B-A type, where A represents a styrenic block and B represents a rubbery block of polyisoprene, polybutadiene, or poly(ethylene/butylene), and resins. Examples of the various block copolymers useful in block copolymer pressure-sensitive adhesives include linear, radial, star and tapered styrene-isoprene block copolymers such as KRATON D1107P, from Shell Chemical Co., Norco, La., and EUROPRENE SOL TE 9110, from EniChem Elastomers Americas, Inc. Houston, Tex.; linear styrene-(ethylene-butylene) block copolymers such as KRATON G1657, from Shell Chemical Co.; linear styrene-(ethylene-propylene) block copolymers such as KRATON G1750X, from Shell Chemical Co.; and linear, radial, and star styrene-butadiene block copolymers such as KRATON D1118X, from Shell Chemical Co., and EUROPRENE SOL TE 6205, from EniChem Elastomers Americas, Inc. The polystyrene blocks tend to form domains in the shape of spheroids, cylinders, or plates that causes the block copolymer pressure-sensitive adhesives to have two-phase structures. Resins that associate with the rubber phase generally develop tack in the pressure-sensitive adhesive. Examples of rubber phase associating resins include aliphatic olefin-derived resins, such as the ESCOREZ 1300 series and the WINGTACK series, from Goodyear Tire and Rubber, Akron, Ohio; rosin esters, such as the FORAL series and the STAYBELITE Ester 10, both from Hercules, Inc.; hydrogenated hydrocarbons, such as the ESCOREZ 5000 series, from ExxonMobil; polyterpenes, such as the PICCOLYTE A series; and terpene phenolic resins derived from petroleum or turpentine sources, such as PICCOFYN A 100, from Hercules, Inc. Resins that associate with the styrenic phase tend to stiffen the pressure-sensitive adhesive. Styrenic phase associating resins include polyaromatics, such as the PICCO 6000 series of aromatic hydrocarbon resins, from Hercules, Inc.; coumarone-indene resins, such as the CUMAR series, from Neville, Pittsburgh, Pa.; and other high-solubility parameter resins derived from coal tar or petroleum and having softening points above about 85° C. such as PICCOVAR 130 alkyl aromatic polyindene resin, from Hercules, Inc., and the PICCOTEX series of α-methylstyrene/vinyl toluene resins, from Hercules. Other materials can be added for special purposes, including rubber phase plasticizing hydrocarbon oils available as TUFFLO 6056 from Lydondell Chemical Co., Houston, Tex., as POLYBUTENE-8 from Chevron Corp., San Ramon, Calif., as KAYDOL, from Chemtura, Philadelphia, Pa., and as SHELLFLEX 371 from Shell Chemical Co.; pigments; antioxidants, such as IRGANOX 1010 and IRGANOX 1076, both from Ciba-Geigy Corp., BUTAZATE, from Uniroyal Chemical Co., Middlebury, Conn., CYANOX LDTP from Cytec Industries, Woodland Park, N.J., and BUTASAN, from Monsanto Co.; antiozonants such as NBC, a nickel dibutyl dithiocarbamate, from E.I. du Pont de Nemours & Co., Wilmington, Del.; liquid rubbers such as VISTANEX LMMH polyisobutylene rubber; and ultraviolet light inhibitors, such as IRGANOX 1010 and TINUVIN P, from Ciba-Geigy Corp.

Polyvinyl ether pressure-sensitive adhesives are generally blends of homopolymers of vinyl methyl ether, vinyl ethyl ether or vinyl isobutyl ether, or blends of homopolymers of vinyl ethers and copolymers of vinyl ethers and acrylates to achieve preferred pressure-sensitive properties. Depending on the degree of polymerization, homopolymers may be viscous oils, tacky soft resins or rubber-like substances. Polyvinyl ethers used as raw materials in polyvinyl ether adhesives include polymers based on: vinyl methyl ether, such as LUTANOL M 40, from BASF, and GANTREZ M 574 and GANTREZ 555, from ISP Corp. Wayne, N.J.; vinyl ethyl ether, such as LUTANOL A 25, LUTANOL A 50 and LUTANOL A 100; vinyl isobutyl ether such as LUTANOL 130, LUTANOL 160, LUTANOL IC, LUTANOL 160D and LUTANOL I 65D; methacrylate/vinyl isobutyl ether/acrylic acid such as ACRONAL 550 D, from BASF. Antioxidants useful to stabilize polyvinyl ether pressure-sensitive adhesives include, for example, IONOX 30 from Shell Chemical Corp., and IRGANOX 1010 from Ciba-Geigy Corp. Other materials can be added for special purposes as described in BASF literature including tackifier, plasticizer and pigments.

Poly-α-olefin pressure-sensitive adhesives, also called a poly(1-alkene) pressure-sensitive adhesives, generally comprise either a substantially non-crosslinked polymer or a non-crosslinked polymer that may have radiation activatable functional groups grafted thereon as described in U.S. Pat. No. 5,209,971 (Babu et al.). The poly(α-olefin) polymer may be self-tacky and/or include one or more tackifying materials. If non-crosslinked, the inherent viscosity of the polymer is generally between about 0.7 and 5.0 deciliter per gram (dL/g) as measured according to ASTM D 2857-93, “Standard Practice for Dilute Solution Viscosity of Polymers”. In addition, the polymer generally is predominantly amorphous. Useful poly-α-olefin polymers include, for example, C₃-C₁₈ poly(α-olefin) polymers, preferably C₅-C₁₂ α-olefins and copolymers of those with C₃ and more preferably C₆-C₈ and copolymers of those with C₃. Tackifying materials are typically resins that are miscible in the poly-α-olefin polymer. The total amount of tackifying resin in the poly-α-olefin polymer ranges between 0 to 150 parts by weight per 100 parts of the poly-α-olefin polymer depending on the specific application. Useful tackifying resins include, for example, resins derived by polymerization of C₅ to C₉ unsaturated hydrocarbon monomers, polyterpenes, and synthetic polyterpenes. Examples of such commercially available resins based on a C₅ olefin fraction of this type are WINGTACK 95 and WINGTACK 15 tackifying resins from Goodyear Tire and Rubber Co. Other hydrocarbon resins include REGALREZ 1078 and REGALREZ 1126 from Hercules Chemical Co., and ARKON P115 from Arakawa Chemical Co., Chicago, Ill. Other materials can be added for special purposes, including antioxidants, fillers, pigments, and radiation activated crosslinking agents.

Silicone pressure-sensitive adhesives comprise two major components, a polymer or gum, and a tackifying resin. The polymer is typically a high molecular weight polydimethylsiloxane or poly(dimethylsiloxane-co-diphenylsiloxane), that contains residual silanol functionality (SiOH) on the ends of the polymer chain, or a block copolymer comprising polydiorganosiloxane soft segments and urea terminated hard segments. The tackifying resin is generally a three-dimensional silicate structure that is end-capped with trimethylsiloxy (i.e., —OSi(CH₃)₃) groups (although other trialkylsiloxy groups may be used), and also contains some residual silanol functionality. Examples of tackifying resins include SR 545, from General Electric Co., Silicone Resins Division, Waterford, N.Y., and MQD-32-2 from Shin-Etsu Silicones of America, Inc., Torrance, Calif. Manufacture of typical silicone pressure-sensitive adhesives is described in U.S. Pat. No. 2,736,721 (Dexter). Manufacture of silicone urea block copolymer pressure-sensitive adhesive is described in U.S. Pat. No. 5,214,119 (Leir et al.). Other materials can be added for special purposes, including, pigments, plasticizers, and fillers. Fillers are typically used in amounts from 0 parts to 10 parts per 100 parts of silicone pressure-sensitive adhesive.

Acrylic pressure-sensitive adhesives generally have a glass transition temperature of about −20° C. or less and may comprise from 100 to 80 weight percent of a C₃-C₁₂ alkyl ester component such as, for example, isooctyl acrylate, 2-ethylhexyl acrylate and n-butyl acrylate and from 0 to 20 weight percent of a polar component such as, for example, acrylic acid, methacrylic acid, ethylene vinyl acetate, N-vinylpyrrolidone, and styrene macromer. Preferably, acrylic pressure-sensitive adhesives comprise from 0 to 20 weight percent of acrylic acid and from 100 to 80 weight percent of isooctyl acrylate.

Acrylic pressure-sensitive adhesives may be self-tacky or tackified. Useful tackifiers for acrylics are rosin esters such as FORAL 85, from Hercules, Inc., aromatic resins such as PICCOTEX LC-55WK, aliphatic resins such as PICCOTAC 95, from Hercules, Inc., and terpene resins such as α-pinene and β-pinene, available as PICCOLYTE A-115 and ZONAREZ B-100 from Arizona Chemical, Phoenix, Ariz. Other materials can be added for special purposes, including hydrogenated butyl rubber, pigments, and curing agents to vulcanize the adhesive partially.

Acrylic pressure-sensitive adhesives can be prepared by prepolymerizing a mixture of polymerizable monomers containing a thermal and/or photoinitiator to form a coatable syrup, coating the coatable syrup, and further polymerizing the coated syrup. Typically, the mixture of polymerizable monomers comprises 50-100 parts by weight of at least one acrylic acid ester of an alkyl alcohol (preferably a non-tertiary alcohol), the alcohol containing from 1 to 14 (preferably 4 to 14) carbon atoms. Included within this class of monomers are, for example, isooctyl acrylate, isononyl acrylate, 2-ethylhexyl acrylate, decyl acrylate, dodecyl acrylate, n-butyl acrylate, methyl acrylate, and hexyl acrylate. Preferred monomers include, for example, isooctyl acrylate, isononyl acrylate, butyl acrylate, and 2-ethylhexyl acrylate.

The acrylic acid ester (“acrylate”) is copolymerized with 0 to 50 parts of at least one copolymerizable monomer which is typically an ethylenically unsaturated polar monomer such as, for example, acrylic acid, methacrylic acid, acrylamide, acrylonitrile, methacrylonitrile, N-substituted acrylamides, hydroxyacrylates, N-vinyllactam, N-vinylpyrrolidone, maleic anhydride, isobornyl acrylate, and itaconic acid.

Exemplary photoinitiators include benzoin ethers such as benzoin methyl ether and benzoin isopropyl ether; substituted phosphine oxides such as 2,4,6-trimethylbenzoyldiphenylphosphine oxide available as LUCIRIN TPO-L from BASF; substituted acetophenones such as 2,2-diethoxyacetophenone, available as IRGACURE 651 photoinitiator from Ciba-Geigy Corp.; 2,2-dimethoxy-2-phenyl-1-phenylethanone, available as ESACURE KB-1 photoinitiator from Sartomer Co., West Chester, Pa.; and dimethoxyhydroxyacetophenone; substituted α-ketols such as 2-methyl-2-hydroxypropiophenone, 2-naphthalenesulfonyl chloride, and 1-phenyl-1,2-propanedione-2-(O-ethoxycarbonyl)oxime. Particularly useful are the substituted acetophenones or 2,4,6-trimethylbenzoyldiphenylphosphine oxide. Preferably, the photoinitiator is present in an amount of from about 0.01 part to about 5 parts by weight, and most preferably, about 0.10 to 2 parts by weight, based upon 100 total parts by weight of monomer.

Prepolymerization can be accomplished by exposure to electromagnetic radiation (such as UV light) or by thermal polymerization. Other methods of increasing the viscosity of the monomer mixture are also available, however, such as the addition of viscosity modifying agents such as, for example, high molecular weight polymers or thixotropic agents such as colloidal silicas. A syrup is a monomeric mixture thickened to a coatable viscosity.

The polymerizable monomer mixture preferably contains a crosslinking agent to enhance the cohesive strength of the resulting adhesive or article. Useful crosslinking agents which also function as photoinitiators are the chromophore-substituted halomethyl-s-triazines disclosed in U.S. Pat. No. 4,330,590 (Vesley) and U.S. Pat. No. 4,329,384 (Vesley et al.). Other suitable crosslinking agents include hydrogen abstracting carbonyls such as anthraquinone and benzophenone and their derivatives, as disclosed in U.S. Pat. No. 4,181,752 (Martens et al.), and polyfunctional acrylates such as, for example, 1,6-hexanediol diacrylate, trimethylolpropane triacrylate, and 1,2-ethylene glycol diacrylate, as well as those disclosed in U.S. Pat. No. 4,379,201 (Heilmann et al.).

The polymerizable mixture of monomers or prepolymerized syrup can be coated onto any suitable substrate including, for example, releasable liners, films (transparent and non-transparent), cloths, papers, non-woven fibrous constructions, metal foils, and aligned filaments.

Afterwards, the mixture of monomers or partially prepolymerized syrup is photopolymerized by irradiating the same with actinic radiation (for example, electromagnetic radiation of 280 to 500 nanometer wavelength and 0.01 to 20 milliwatts per square centimeter (mW/cm²) average light intensity) to affect about 5 to 95 percent conversion of the monomeric mixture, or pre-polymerized syrup, to form a pressure-sensitive adhesive. If desired, coatable syrups may include a blowing agent and/or be frothed (for example, mechanically or using compressed gas).

Irradiation is preferably carried out in the absence of oxygen. Thus, it is normally carried out in an inert atmosphere such as nitrogen, carbon dioxide, helium, argon, and the like. Air can also be excluded by sandwiching the liquid polymerizable mixture between layers of solid sheet material and irradiating through the sheet material. As will be appreciated by those skilled in the art, such material can have low adhesion surfaces and can be removed after polymerization is complete or one such surface can be a tape backing material. Preferably, the stages of irradiation are conducted continuously, or in-line without interruption of the polymerization process, i.e., the coated mixture is exposed to the first stage irradiation (pre-polymerization) and then immediately exposed to the second stage irradiation (polymerization) with no interruption of the inert atmosphere between the stages.

The conductive resilient hollow microspheres (and optional additional components such as, for example, conductive filler particles) may be dispersed within the adhesive matrix at any stage of this process prior to coating and curing. For example, the conductive resilient hollow microspheres may be dispersed in the monomer mixture, in the monomer mixture with added modifying agent or in the coatable syrup. For ease of dispersal, the conductive resilient hollow microspheres (and optional conductive filler particles) are typically added to the monomer mixture or the coatable syrup.

The conductive resilient hollow microspheres may be included in the adhesive layer in an amount of from 25 to 50 percent by volume, based on the total volume of the adhesive layer, preferably from 31 to 41 percent by volume, based on the total volume of the adhesive layer, although other amounts may also be used.

Optional fillers may be, for example, solid or hollow, and may have uniform composition throughout, or they may be composites. Optional conductive fillers include metal particles, metal fibers, and metal-coated hollow glass microspheres. Composite fibers may, for example, have one or more conductive sheath layers surrounding a polymeric or glass core. Examples of conductive fibers include fibers of glass or polymeric material that have a metal (e.g., nickel, gold, silver, copper, or an alloy thereof) coating thereon. If present, conductive fillers may be included in the adhesive layer in an amount of from 1 to 10 percent by weight, based on the total weight of the adhesive layer, although other amounts may also be used.

Conductive coatings may be applied to particles and fibers used in the present disclosure using any suitable method. In the case of metallic coatings, sputter coating methods and thermal vapor coating methods may be useful. Such methods are known to those of skill in the art.

The insulating adhesive component may further include additives such as, for example, tackifiers, pigments, fillers, fragrances, plasticizers, antioxidants, UV absorbers, and light stabilizers.

In some embodiments, the fillers may comprise conductive fillers such as for example, conductive metal particles, metal coated glass microspheres (hollow and/or solid), and/or conductive fibers. Examples of suitable conductive filler particles include conductive metal particles (e.g., silver, gold, nickel, and/or copper particles), glass or rigid polymeric microspheres (hollow or solid) having a conductive metal (e.g., silver, gold, nickel, and/or copper) coating thereon.

The amount of conductive resilient hollow microspheres may be included in the adhesive compositions in any amount. For example, they may be include in an amount of from 0.5 to 80 percent by volume, from 20 to 80 percent by volume, or from 30 to 70 percent by volume, based on the total volume of the adhesive composition.

Adhesive compositions according to the present disclosure are useful, for example, for making conductive and/or electromagnetic interference (EMI) shielding adhesive articles such as tapes and gaskets, and radiofrequency (RF) absorbers. Adhesive compositions according to the present disclosure can be applied as a layer onto one or more substrates having low surface energy surfaces to form transfer adhesive articles such as, for example, transfer tapes and sheets. The layer of the adhesive composition typically has thickness in a range of from at least 0.2 mm to 10 mm, more typically from 0.3 mm to 5 mm, however greater and lesser thicknesses may also be used.

Referring now to FIG. 2, exemplary adhesive article 200 comprises layer of the adhesive composition 210. Adhesive composition 210 comprises conductive resilient hollow microspheres 100, insulating adhesive component 250, and optional conductive filler particles 260. Layer of the adhesive composition 210 is releasably adhered to a first major surface 220 of first substrate 230. Adhesive article 200 optionally further comprises second substrate 240, wherein the layer of the adhesive composition is releasably adhered to a major surface 250 of second substrate 240. Layer of the adhesive composition 210 is disposed between first substrate 230 and second substrate 240.

Another embodiment of an adhesive article in roll form is shown in FIG. 3. Referring now to FIG. 3, exemplary adhesive article 300 comprises layer of the adhesive composition 210. Substrate 330 has a second major surface 340 opposite first major surface 320. Layer of the adhesive composition 210 is releasably adhered to a first major surface 320 and second major surface 340 of substrate 330.

Examples of useful substrates (including first substrate 230, second substrate 260, and substrate 330) include papers, polymer films, foils, and nonwovens having a low energy coating (e.g., polyolefin, silicone, fluorosilicone, or fluorocarbon coating) thereon or made of a low surface energy material such as, for example, polyethylene or polypropylene. Such coatings are known as release coatings in the art, and the above substrates with such coatings are often termed “release carriers” or “release liners” in the art and are commercially available from numerous sources.

Objects and advantages of this disclosure are further illustrated by the following non-limiting examples, but the particular materials and amounts thereof recited in these examples, as well as other conditions and details, should not be construed to unduly limit this disclosure.

### EXAMPLES

Unless otherwise noted, all parts, percentages, ratios, etc. in the Examples and the rest of the specification are by weight.

### Metallization of Particles by Physical Vapor Deposition Method

The apparatus and coating method for metal coating of 300 milliliters (mL) volume size of hollow microspheres was similar to that described in the U.S. Pat. No. 7,727,931 (Brey et al.).

For 40 mL volume batches, the particle agitator used was a hollow cylinder (6 cm long×5.5 cm diameter horizontal) with a rectangular opening 34 (4.5 cm×3.5 cm) in the top.

For 2000 mL volume batches, the particles were coated using a hollow cylinder particle agitator (24.3 cm long×19.05 cm diameter horizontal) with a rectangular opening (16.51 cm×13.46 cm) in the top.

### Resiliency Test

Using a 2.5-mL graduated syringe tube of inside diameter about 8 mm, uncoated hollow microspheres were placed into the tube with sufficient agitation and pressure to densely pack the particles to their least (uncompressed) volume. This volume was about 0.9 mL. This volume was regarded as the original volume. Then, with an applied plunger pressure of 20 megapascals (MPa), the hollow microspheres were compressed, resulting in a total volume of 0.2 mL, and the pressure was relieved. The degree of volume recovered was observed. If at least 0.8 mL was obtained then the hollow microspheres passed this test.

### Bulk Electrical Resistance Evaluation

Method I: Bulk resistance of metal-coated hollow microspheres/powders was evaluated using the following procedure. The test cell consisted of a Delrin thermoplastic block containing a 2.54 cm×2.54 cm square cavity. The bottom of the cavity was covered by a gold plated brass electrode. The second electrode was a square block of gold plated brass which fitted into the cavity, and weighed 200 g. The powder to be tested was placed in the cavity, then the top electrode block was inserted which exerted a total pressure of 0.44 psi (3 kPa) on the powder. The electrodes were connected to a digital multimeter to measure resistance. Resistance values were obtained when the powder bed was 0.1 cm high.

Method II: Bulk resistance of film composites were measured using the same set-up as described in Method I, except that the film composites were die cut to 2.54 cm×2.54 cm square and placed in the cavity. Additional weights were used on the top electrode to determine the bulk electrical resistance values at various pressures. Actual sample thickness was measured using a caliper.

### Example 1

Acrylonitrile-methacrylonitrile copolymer resilient hollow microspheres (bulk density 0.1 g/mL, average particle diameter 15-30 microns, 40 mL (about 2.5 g) obtained as MP11 from Guangzhou Eco. and Chemie Trading Co. Ltd., Guangzhou, Guangdong, China) were dried for one hour at 100° C. in a convection oven. The dried microspheres were placed into the particle agitator apparatus in a vacuum chamber of sputtering apparatus. The vacuum chamber was evacuated to a pressure of 5×10⁻⁵ torr (1 mPa), and argon sputtering gas was introduced to reach a nominal pressure of 5 millitorr (0.7 Pa). Silver deposition was then started by applying a cathodic sputter power of 50 watts. The particle agitator shaft was rotated at about 4 rpm during the silver deposition process. The power was stopped after 20 hours. The chamber was backfilled with air and the silver coated particles were removed. The silver sputter target weight loss was 25.66 g. Based on the capture efficiency of the agitator, the amount of silver coated on the hollow microspheres was calculated to be approximately 70 percent by weight, corresponding to a thickness of the silver coating of 40 nm.

### Example 2

The procedure of Example 1 was repeated, except that a 12.7 cm×20.32 cm rectangular stainless steel 304 target with a thickness of 1.27 cm was used, and the cathodic power was increased to 500 watts, resulting in stainless steel-coated conductive hollow microspheres. The calculated thickness of the stainless steel coating was 38 nm.

### Example 3

Acrylonitrile-methacrylonitrile copolymer resilient hollow microspheres obtained as MP14 copolymer microspheres from Guangzhou Eco. and Chemie Trading Co. Ltd. (40 mL, 0.3 g, of a 0.01 g/mL, average particle diameter 20-100 microns, China) were used and the procedure of Example 1 was repeated, yielding silver-coated hollow copolymer microspheres. The calculated thickness of the silver coating was 27 nm.

### Example 4

The procedure of Example 3 was repeated, except that a stainless steel 304 target was used and the cathodic power was increased to 500 watts, resulting in stainless steel 304-coated conductive hollow microspheres. The calculated thickness of the stainless steel coating was 30 nm

### Comparative Example A

Comparative Example A was SANLIAN 4# nickel powder (35 microns average particle diameter, from Shanghai Xuyu Powder Metallurgy Co., Ltd., Shanghai, China).

### Comparative Example B

Comparative Example B was silver-coated glass bubbles (15 microns average particle diameter).

TABLE 1

| | BULK ELECTRICAL | |
|---|---|---|
| | RESISTANCE, | |
| | Method I, | |
| EXAMPLE | milliohms (mΩ) | COMPRESSIBILITY |
| 1 | 0.3 | Compressible but no recovery |
| 2 | 16.0 | Compressible but no recovery |
| 3 | 0.09 | Compressible but no recovery |
| 4 | 12.0 | Compressible but no recovery |
| Comparative | 1.5 | Not Compressible |
| Example A | | |
| Comparative | 0.3 | Not Compressible |
| Example B | | |

### Example 5

Elastic polymeric hollow microspheres, PM6550, were obtained from Sphere One Inc., Chattanooga, Tenn. It is a copolymer of acrylonitrile and methacrylonitrile with isopentene as blowing agent (particle size distribution of: d₁₀=35.07 μm, d₅₀=73.11 μm, d₉₀=114.74 μm). 40 mL of the polymeric bubbles (0.72 g) were dried for one hour at 100° C. in a convection oven. The dried microspheres were placed into the particle agitator apparatus in a vacuum chamber of sputtering. The vacuum chamber was evacuated to less than 5×10⁻⁵ torr (1 mPa), and argon sputtering gas was introduced to reach a pressure of about 10 millitorr (0.7 Pa). Silver deposition was then started by applying a cathodic sputter power of 50 watts. The particle agitator shaft was rotated at about 4 rpm during the silver deposition process. The power was stopped after 10 hours. The chamber was backfilled with air and the silver-coated particles were removed. The silver sputter target weight loss was 10.82 g. Based on the capture efficiency of the agitator, the thickness of silver coated on the hollow microspheres was calculated to be 30 nm.

### Examples 6-8

The procedure in Example 5 was repeated except that the argon sputtering gas was introduced to reach a pressure of about 25 millitorr (3.3 Pa) in Example 6, 50 millitorr (6.7 Pa) in Example 7, and 75 millitorr (10 Pa). The silver target weight loss was 16.07 g and 15.06 g, and 18.65 g respectively. The coating duration was varied to obtain a corresponding silver coating thickness of 30 nm.

Resiliency Tests were performed for the coated hollow spheres reported in Table 2 (below).

TABLE 2

| | SPUTTER | | | | |
|---|---|---|---|---|---|
| | PROCESS | PROCESS | COATING | RESILIENCY | |
| | PRES- | DURA- | THICK- | TEST | |
| EXAM- | SURE | TION | NESS | Compress- | |
| PLE | (Pa) | (hours) | (nm) | ibility | Recovery |
| 5 | 0.7 | 10 | 30 | yes | no |
| 6 | 3.3 | 15 | 30 | yes | yes |
| 7 | 6.7 | 15 | 30 | yes | yes |
| 8 | 10 | 24 | 30 | yes | yes |

### Comparative Example C

A conductive adhesive transfer tape was prepared by combining with mixing for one hour under high shear conditions, 177 g of QS1617 acrylic adhesive (acrylic adhesive preliminarily mixed with tackifier (commercially available from Quick Stick Enterprise Co., Ltd., Taiwan), 1.4 g of 3C75 (crosslinker that is commercially available from Quick Stick Enterprise Co., Ltd.), and 28.5 g of ethyl acetate. Next, 74 g of SANLIAN 4# nickel powder were added with continued mixing for 30 minutes. The resultant mixture was coated by manually at a wet coating thickness of 196 microns onto 3-mil polyester film, and dried in an oven a 105° C. for 10 minutes. The coated film was cooled in air and laminated to a polyester film liner.

### Example 9

PM6550 hollow microspheres (1500 mL, 27.64 g) were coated with silver using a 2000 mL particle agitator apparatus. Silver was coated at an argon process pressure of 50 millitorr (6.7 Pa) by applying a cathodic power of 150 watts for 46 hours. Silver coated hollow microsphere powders were tested for resistance and resiliency.

For Example 9, the procedure of Comparative Example C was repeated, except that the Nickel powder was replaced with 1.4 g of the silver-coated PM6550 hollow microspheres prepared above.

Characteristics of these conductive adhesive transfer tapes are reported in Table 3 (below).

TABLE 3

| | COMPARATIVE | | EXAMPLE | |
|---|---|---|---|---|
| CHARACTERISTIC | EXAMPLE C | | 9 | |
| Adhesive layer thickness | 41 | microns | 41 | microns |
| Bulk Electrical Resistance, Method II | 4.7 | mΩ | 5.2 | mΩ |
| 180 degree peel strength measured | 0.689 | N/mm | 0.692 | N/mm |
| according to ASTM test method | | | | |
| D1000-10 using Stainless Steel 304 | | | | |
| test panel as the substrate | | | | |
| Thickness of adhesive layer under | 41 | microns | 41 | microns |
| applied compressive pressure of | | | | |
| 0.1 kg/inch² (1.5 kPa) | | | | |
| Average thickness of adhesive layer | 39 | microns | 32 | microns |
| under applied compressive pressure | | | | |
| of 1 kg/inch² (15 kPa) | | | | |
| Average thickness of adhesive layer | 34 | microns | 28 | microns |
| under applied compressive pressure | | | | |
| of 5 kg/inch² (76 kPa) | | | | |

### Comparative Example D

A silicone gasket was prepared by combining with mixing for 10 minutes under high shear conditions, 50 g of KET-187A/B (A:B=1:1) curable silicone resin (80 percent by weight solids in xylene, from Shin-Etsu Silicone Taiwan Co., Ltd, Taiwan), 50 g of xylene, and 74 g of SANLIAN 4# nickel powder (particle size distribution: d₁₀=18.96 μm, d₅₀=45.06 μm, d₉₀=73.98 μm, from Shanghai Xuyu Powder Metallurgy Co., Ltd., Shanghai, China). The resultant mixture was dip coated onto a 1080 fiberglass 40 micron-thick fiberglass mesh and cured at 120° C. for 5 minutes. The resultant silicone gasket (including the fiberglass mesh) had a thickness of 1.35 mm.

### Example 10

The procedure of Comparative Example D was repeated, except that the nickel powder was replaced with 2.5 g of silver coated PM6550 from Example 9.

### Example 11

The procedure of Comparative Example D was repeated, except 74 g of SANLIAN 4# nickel powder was replaced by a 36.5 g hybrid conductive mixture that is a mixed by 35 g of SANLIAN 4# nickel powder (particle size distribution: d₁₀=18.96 μm, d₅₀=45.06 μm, d₉₀=73.98 μm) and 1.5 g of conductive resilient hollow microsphere from Example 9.

Characteristics of silicone gaskets of Comparative Example D and Examples 10-11 are reported in Tables 4 and 5 (below).

TABLE 4

| | EXAMPLE | | COMPARATIVE | | EXAMPLE | |
|---|---|---|---|---|---|---|
| CHARACTERISTIC | 10 | | EXAMPLE D | | 11 | |
| Thickness including | 0.9 | mm | 0.8 | mm | 1.08 | mm |
| fiberglass sheet in | | | | | | |
| millimeters | | | | | | |
| Bulk Electrical | 135 | mΩ | 110 | mΩ | 125 | mΩ |
| Resistance, Method II | | | | | | |
| in milliohms (mΩ) at | | | | | | |
| 50 psi (345 kPa) | | | | | | |

TABLE 4

| COMPRES- | | | |
|---|---|---|---|
| SIVE | | | |
| PRESSURE, | COMPAR- | | |
| newtons/in² | ATIVE | | |
| (N/cm²) | EXAMPLE D | EXAMPLE 10 | EXAMPLE 11 |
| 10 (1.5) | 0.871 mm | 0.882 mm | 0.1.058 mm |
| | thickness, | thickness, | thickness, |
| | 1% compression | 2% compression | 2% compression |
| 50 (7.8) | 0.792 mm | 0.765 mm | 0.950 mm |
| | thickness, | thickness, | thickness, |
| | 10% compression | 15% compression | 12% compression |
| 125 (19.4) | 0.686 mm | 0.576 mm | 0.778 mm |
| | thickness, | thickness, | thickness, |
| | 22% compression | 36% compression | 28% compression |
| 250 (38.8) | 0.625 mm | 0.432 mm | 0.594 mm |
| | thickness, | thickness, | thickness, |
| | 29% compression | 52% compression | 45% compression |
| 500 (77.5) | 0.572 mm | 0.279 mm | 0.432 mm |
| | thickness, | thickness, | thickness, |
| | 35% compression | 69% compression | 60% compression |

Other modifications and variations to the present disclosure may be practiced by those of ordinary skill in the art, without departing from the spirit and scope of the present disclosure, which is more particularly set forth in the appended claims. It is understood that aspects of the various embodiments may be interchanged in whole or part or combined with other aspects of the various embodiments. All cited references, patents, or patent applications in the above application for letters patent are herein incorporated by reference in their entirety in a consistent manner. In the event of inconsistencies or contradictions between portions of the incorporated references and this application, the information in the preceding description shall control. The preceding description, given in order to enable one of ordinary skill in the art to practice the claimed disclosure, is not to be construed as limiting the scope of the disclosure, which is defined by the claims and all equivalents thereto.

1-15. (canceled)

16. A conductive resilient hollow microsphere comprising a conductive layer enclosing a resilient polymeric hollow microsphere.

17. The conductive resilient hollow microsphere of claim 16, wherein the resilient polymeric hollow microsphere comprises a copolymer of acrylonitrile and methacrylonitrile.

18. The conductive resilient hollow microsphere of claim 16, wherein the conductive layer comprises silver or stainless steel.

19. An adhesive composition comprising:
an insulating adhesive component; and
a plurality of conductive resilient hollow microspheres according to claim 16.

20. The adhesive composition of claim 19, wherein the insulating adhesive component comprises at least one of an acrylic adhesive or a silicone adhesive.

21. The adhesive composition of claim 19, wherein the adhesive composition is a pressure-sensitive adhesive.

22. The adhesive composition of claim 19, wherein the pressure-sensitive adhesive further comprises conductive filler particles.

23. An adhesive article comprising a layer of the adhesive composition of claim 20, wherein the layer of the adhesive composition is releasably adhered to a first major surface of a first substrate.

24. The adhesive article of claim 23, further comprising a second substrate, wherein the layer of the adhesive composition is releasably adhered to a major surface of a second substrate, and wherein the layer of the adhesive composition is disposed between the first substrate and the second substrate.

25. The adhesive article of claim 24, wherein the substrate has a second major surface opposite the first major surface, and wherein the layer of the adhesive composition is releasably adhered to the second major surface of the first substrate.

26. A method comprising contacting resilient polymeric hollow microspheres with a vapor of a metal at a pressure in the range of from 1.33 pascals to 13.33 pascals, inclusive, for at least sufficient time to deposit a substantially uniform and complete layer of the metal onto the surface of the resilient organic microspheres.

27. The method of claim 26, wherein the resilient organic microspheres are hollow.

28. The method of claim 26, wherein the pressure is in the range of from 2 pascals to 6.67 pascals.

29. The method of claim 26, wherein the pressure is in the range of from 3.33 pascals to 6.67 pascals.

30. The method of claim 26, wherein the vapor of the metal is generated by magnetron sputtering.
